(19) United States
(12) Patent Application Publication
(10) Pub. No.: US 2026/0244114 A1
(43) Pub. Date: Aug. 20, 2026

(54) METHOD AND SYSTEM FOR SIMULATING OVERLAY CORRECTION INDUCED IMAGING IMPACT IN LITHOGRAPHY

(71) Applicant: ASML NETHERLANDS B.V., Veldhoven (NL)

(72) Inventors: Duan-Fu Stephen HSU, Fremont, CA (US); Jialei TANG, San Jose, CA (US); Johannes Jacobus Matheus BASELMANS, Oirschot (NL); Dezheng SUN, Palo Alto, CA (US)

(73) Assignee: ASML NETHERLANDS B.V., Veldhoven (NL)

(21) Appl. No.: 19/469,356

(22) PCT Filed: Mar. 29, 2024
(86) PCT No.: PCT/EP2024/058791

§ 371 Date: Sep. 25, 2025

Related U.S. Application Data
(60) Provisional application No. 63/461,172, filed on Apr. 21, 2023.

(51) Int. Cl. G03F 7/00

(52) U.S. Cl. CPC G03F 7/70633; G03F 7/705

(57) ABSTRACT

A method and system for obtaining fading data related to prescribed overlay correction performed by a lithographic apparatus during a lithography process. The lithography process may be simulated based on the fading data to predict imaging of patterns from the lithography process. The simulation predicts a set of patterning parameters that is indicative of imaging impact due to the overlay correction. Based on the predicted impact, the patterning parameters or the overlay correction terms may be adjusted to minimize the imaging impact prior to patterning the substrate.

### CROSS-REFERENCE TO RELATED APPLICATIONS

This application claims priority of U.S. application 63/461,172 which was filed on 21 Apr. 2023 and which is incorporated herein in its entirety by reference.

### TECHNICAL FIELD

The embodiments provided herein relate to semiconductor manufacturing, and more particularly to adjusting overlay correction based on computational lithography simulation.

### BACKGROUND

A lithographic apparatus is a machine that applies a desired pattern onto a target portion of a substrate. The lithographic apparatus can be used, for example, in the manufacture of integrated circuits (ICs). For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects.

### BRIEF SUMMARY

In some embodiments, the techniques described herein relate to a method for determining imaging impact due to overlay correction in a lithography process, the method including: obtaining fading data related to prescribed overlay correction performed by a lithographic apparatus during a lithography process; and simulating the lithography process based on the fading data to predict imaging of patterns from the lithography process.

In some embodiments, the techniques described herein relate to a method for determining imaging impact due to overlay correction in a lithography process, the method including: obtaining fading data related to prescribed overlay correction performed by a lithographic apparatus during a lithography process; converting the fading data to wavefront expressions as an input to predict imaging of patterns; and simulating the lithography process based on the wavefront expressions to predict the imaging of patterns.

In some embodiments, the techniques described herein relate to a method for simulating a lithography process based on a dynamic pupil, the method including: obtaining a set of pupil shapes corresponding to a target pupil, the set of pupil shapes corresponding to a variation of the target pupil at multiple locations along a scanning direction of a lithographic apparatus; and simulating a lithography process based on the set of pupil shapes to predict imaging of patterns from the lithography process.

In some embodiments, there is provided a non-transitory computer readable medium having instructions that, when executed by a computer, cause the computer to execute a method of any of the above embodiments.

In some embodiments, there is provided an apparatus includes a memory storing a set of instructions and a processor configured to execute the set of instructions to cause the apparatus to perform a method of any of the above embodiments.

### BRIEF DESCRIPTION OF THE DRAWINGS

Embodiments will now be described, by way of example only, with reference to the accompanying drawings in which:

FIG. 1 illustrates a block diagram of various subsystems of a lithographic projection apparatus, according to an embodiment.

FIG. 2 is a schematic diagram of a lithographic projection apparatus, according to an embodiment.

FIG. 3 illustrates an exemplary flow chart for simulating lithography in a lithographic projection apparatus, according to an embodiment.

FIG. 4 is a block diagram of an exemplary system for simulating imaging impact in a lithography process due to overlay correction, consistent with various embodiments.

FIG. 5 shows examples of fading data, linear portion of the fading data, wavefront expressions used in simulating imaging impact in a lithography process due to overlay correction, consistent with various embodiments.

FIG. 6 is a flow diagram of an exemplary method for simulating imaging impact in a lithography process due to overlay correction, consistent with various embodiments.

FIG. 7 is a flow diagram of a method for simulating imaging impact due to overlay correction using a linear portion of the fading data, consistent with various embodiments.

FIG. 8 is a flow diagram of a method for adjusting overlay correction based on imaging impact, consistent with various embodiments.

FIG. 9 illustrates a dynamic pupil whose shape varies along the scanning direction, consistent with various embodiments.

FIG. 10 is a flow diagram of a method for simulating imaging impact due to overlay correction considering an effect of a dynamic pupil, consistent with various embodiments.

FIG. 11 shows an example of a slit y illumination profile, consistent with various embodiments.

FIG. 12 is a block diagram of an example computer system, according to an embodiment.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

A lithographic apparatus is a machine that applies a designed pattern onto a target portion of a substrate. This process of transferring the designed pattern to the substrate is called a patterning process. The patterning process can include a patterning step to transfer a pattern from a patterning device (such as a mask) to the substrate. Various variations (e.g., variations in the patterning process or the lithographic apparatus) can potentially limit lithography implementation for semiconductor high volume manufacturing (HVM). In some embodiments, an “overlay” is determined as a layer-to-layer placement error between two features of two layers (e.g., adjacent layers) which are designed to align or have a known relationship. An overlay correction may be performed to minimize any overlay error. The overlay correction may be implemented by coordinating the movements of reticle stage, wafer stage or an optical column of the lithographic apparatus (e.g., lens or mirrors) during processing. Overlay corrections within an EUV scanner are implemented exclusively by reticle and wafer stage routing modulations and without any adjustments of the projection optics box. The overlay correction may introduce certain imaging errors such as fading (e.g., blurring). The active overlay correction induced image fading is the imaging degradation due to a deviation of a specified wafer or reticle stage movement from a requested scanner set point of wafer and reticle stage movement. Image fading is the degradation of an imaged feature's fidelity due to mismatch between wafer and reticle stage synchronization. Specifically, as the imaged feature moves though the slit any uncorrelated movement of either the reticle or the wafer stage will introduce feature edge blurring and consequently lead to image degradation due to a lower image log-slope. Besides static x,y translations and symmetric field rotations all other intrafield overlay corrections result in dynamic scan routing modulations and therefore contribute to image fading. The magnitude depends on the specific overlay correction term's routing characteristics and is expressed as the moving standard deviation (MSD) error.

Such imaging degradation has an impact on one or more patterning parameters such as critical dimension (CD), CD uniformity (CDU), image log slope (ILS), normalized image log slope (NILS), edge placement error (EPE) distribution, process window (PW), line edge roughness (LER), local CDU (LCDU), or pattern placement error (PPE). Conventionally, there lacks a mechanism to simulate the wafer imaging impact caused by a prescribed overlay correction by the lithography apparatus, and therefore, may not provide a way to know the imaging impact due to the overlay correction until after patterns are printed on the substrate.

Disclosed are embodiments for simulating a lithography process to predict imaging of patterns on a substrate by incorporating image fading caused due to prescribed overlay correction during a lithography process. The simulation may predict a patterning parameter (e.g., lithography process or lithography apparatus related parameter) such as CD, CDU, ILS, NILS, EPE distribution, PW, LER, PPE, a resist effect, an aberration of a scanner of the lithographic apparatus, or measured mask data. The predicted parameter value may then be compared with patterning specification data (e.g., data having permissible or acceptable parameter value for a patterning process) to determine whether the imaging of a pattern is impacted (e.g., affected adversely). If the imaging is impacted, the prescribed overlay correction may be adjusted to minimize the imaging impact. For example, overlay correction terms may be adjusted, an overlay correction may be simulated to determine if the adjusted overlay correction terms satisfy the parameters of the overlay correction process, and the adjusted overlay correction parameters may then be used to predict the fading effect, which may then be used to determine the imaging impact. The above process may be continued until the imaging impact is minimized or a balance between the desired overlay correction and the imaging impact is obtained.

The fading data associated with the image fading includes position errors of a feature over the width of a slit during scanning and across the full length over a scanning field of the lithography process. The fading data may be described by moving standard deviation (MSD), which indicates slit intensity weighted standard deviation per field over exposure time across slit length. MSD may be determined based on simulating modulation of at least one of a wafer stage, a reticle stage, or an optical column of the lithographic apparatus. In some embodiments, the simulation methods use wavefront expressions (e.g., Zernike parameters, Tatian parameters etc.) to simulate the imaging impact. The fading data (e.g., MSD) may be converted to wavefront (e.g., Tatian, Zernike, etc.) such that the imaging impact from the converted wavefront is similar to (e.g., equivalent to or an approximation of) the imaging impact from the fading data and the converted wavefront may be used for simulating the imaging impact.

MSD can be expressed as a combination of a linear part and high order part. Any portion of the MSD may be converted to the wavefront expressions for use in imaging impact prediction. In some embodiments, a linear part of the fading data (e.g., linear part of the MSD, MSDₗᵢₙ) is extracted from the fading data and converted to the wavefront expressions (e.g., linear Zernike parameters such as Z2 and Z3 that control the MSDₗᵢₙ), which are then used to simulate the imaging impact. By simulating a lithography process based on the fading effect due to overlay correction, the impact on imaging of patterns may be determined. Further, based on the predicted impact, the patterning parameters or the overlay correction terms may be adjusted to minimize the imaging impact prior to patterning the substrate thereby minimizing a defect in printing a pattern on a substrate.

In the present disclosure, although specific reference may be made to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm). In the present document, the term “radiation source” or “source” is used to encompass all types of sources of radiation, including laser sources, incandescent sources, etc. which may include treatment of the radiation between the radiation source and the target or other parts of the optics, including filtering, collimating, focusing, etc.

A patterning device can comprise, or can form, one or more design layouts. The design layout can be generated utilizing CAD (computer-aided design) programs. This process is often referred to as EDA (electronic design automation). Most CAD programs follow a set of predetermined design rules in order to create functional design layouts/patterning devices. These rules are set based processing and design limitations. For example, design rules define the space tolerance between devices (such as gates, capacitors, etc.) or interconnect lines, to ensure that the devices or lines do not interact with one another in an undesirable way. One or more of the design rule limitations may be referred to as a “critical dimension” (CD). A critical dimension of a device can be defined as the smallest width of a line or hole, or the smallest space between two lines or two holes. Thus, the CD regulates the overall size and density of the designed device. One of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective; binary, phase-shifting, hybrid, etc.), examples of other such patterning devices include a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. Examples of other such patterning devices also include a programmable LCD array. An example of such a construction is given in U.S. Pat. No. 5,229,872, which is incorporated herein by reference.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

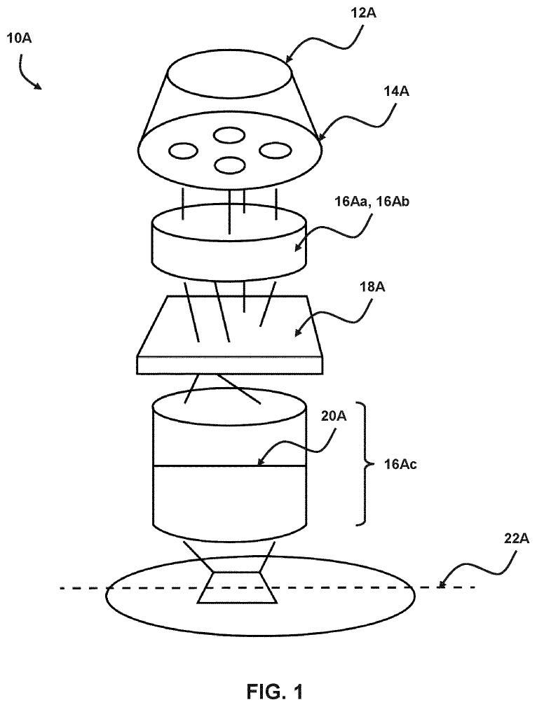

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (the lithographic projection apparatus itself need not have the radiation source), illumination optics which, e.g., define the partial coherence (denoted as sigma) and which may include optics 14A, 16Aa and 16Ab that shape radiation from the source 12A; a patterning device (or mask) 18A; and transmission optics 16Ac that project an image of the patterning device pattern onto a substrate plane 22A.

A pupil 20A can be included with transmission optics 16Ac. In some embodiments, there can be one or more pupils before and/or after mask 18A. As described in further detail herein, pupil 20A can provide patterning of the light that ultimately reaches substrate plane 22A. An adjustable filter or aperture at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e., radiation) to a patterning device and projection optics direct and shape the illumination, via the patterning device, onto a substrate. This is not to disclaim that the source does not itself provide patterning, directing, or shaping to the radiation or that patterning, directing, or shaping does not occur between the source and the projection optics. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157360, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

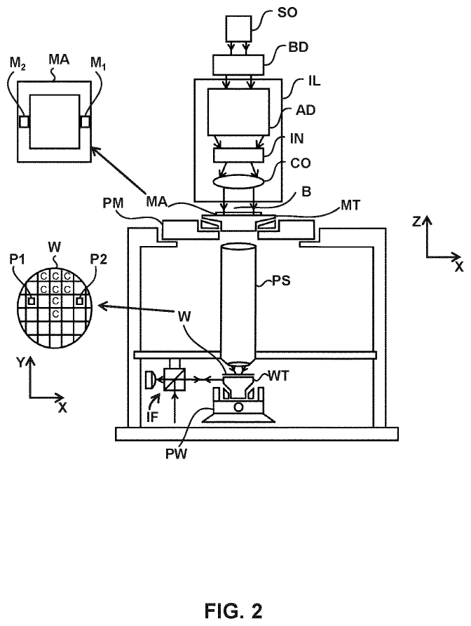

FIG. 2 schematically depicts an exemplary lithographic projection apparatus whose illumination source could be optimized utilizing the methods described herein. The apparatus comprises:
an illumination system IL, to condition a beam B of radiation. In this particular case, the illumination system also comprises a radiation source SO;
a first object table (e.g., mask table, patterning device table or reticle stage) MT provided with a patterning device holder to hold a patterning device MA (e.g., a reticle), and connected to a first positioner to accurately position the patterning device with respect to item PS;
a second object table (substrate table or wafer stage) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed conditioning means, such as a beam expander Ex, for example. The illuminator IL may comprise adjusting means AD for setting the outer or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 2 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

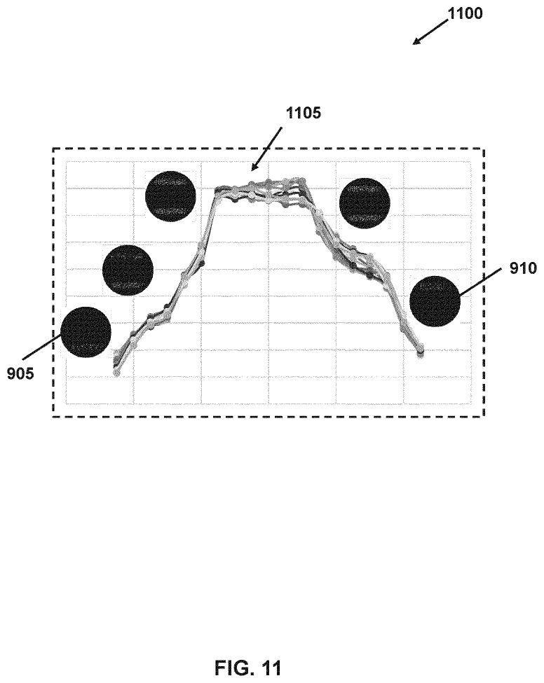

The beam B subsequently intercepts the patterning device MA, which is held on a patterning device table MT. Having traversed the patterning device MA, the beam B passes through the lens PS, which focuses the beam B onto a target portion C of the substrate W. With the aid of the second positioning means (and interferometric measuring means IF), the substrate table WT can be moved accurately, e.g. so as to position different target portions C in the path of the beam B. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 11. However, in the case of a wafer stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x or y directions so that a different target portion C can be irradiated by the beam B;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PS (typically, M=¼ or ⅕). In this manner, a relatively large target portion C can be exposed, without having to compromise on resolution.

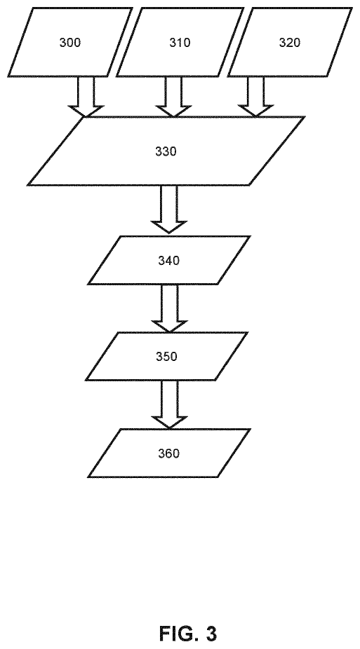

FIG. 3 illustrates an exemplary flow chart for simulating lithography in a lithographic projection apparatus, according to an embodiment. As will be appreciated, the models may represent a different patterning process and need not comprise all the models described below. A source model 300 represents optical characteristics (including radiation intensity distribution, bandwidth and/or phase distribution) of the illumination of a patterning device. The source model 300 can represent the optical characteristics of the illumination that include, but not limited to, numerical aperture settings, illumination sigma (o) settings as well as any particular illumination shape (e.g., off-axis radiation shape such as annular, quadrupole, dipole, etc.), where σ (or sigma) is outer radial extent of the illuminator.

A projection optics model 310 represents optical characteristics (including changes to the radiation intensity distribution and/or the phase distribution caused by the projection optics) of the projection optics. The projection optics model 310 can represent the optical characteristics of the projection optics, including aberration, distortion, one or more refractive indexes, one or more physical sizes, one or more physical dimensions, etc.

The patterning device/design layout model module 320 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 320 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 330 can be simulated from the source model 300, the projection optics model 310 and the patterning device/design layout model module 320. An aerial image (AI) is the radiation intensity distribution at substrate level. Optical properties of the lithographic projection apparatus (e.g., properties of the illumination, the patterning device, and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 350 can be simulated from the aerial image 330 using a resist model 340. The resist model can be used to calculate the resist image from the aerial image, an example of which can be found in U.S. Pat. No. 8,200,468, the disclosure of which is hereby incorporated by reference in its entirety. The resist model 340 typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation, and polarization effects—may be captured as part of the projection optics model 310.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 3-dimensional aerial (and resist) image.

In an embodiment, the resist image 350 can be used an input to a post-pattern transfer process model module 360. The post-pattern transfer process model module 360 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

The following paragraphs describe a system and a method for simulating a lithography process (also referred to as “patterning process”) to predict impact on imaging of patterns on a substrate due to overlay correction. The simulation may predict a patterning parameter (e.g., lithography process or lithography apparatus related parameters) such as CD, CDU, ILS, NILS, EPE distribution, PW, LER, LCDU, PPE, a resist effect, an aberration of a scanner of the lithographic apparatus, or measured mask data based on fading effect caused due to the overlay correction. The predicted parameter value may be compared with acceptable parameter values defined in patterning specification data to determine whether imaging of a pattern is impacted (e.g., affected adversely). If the imaging is impacted, the prescribed overlay correction may be adjusted to minimize the imaging impact.

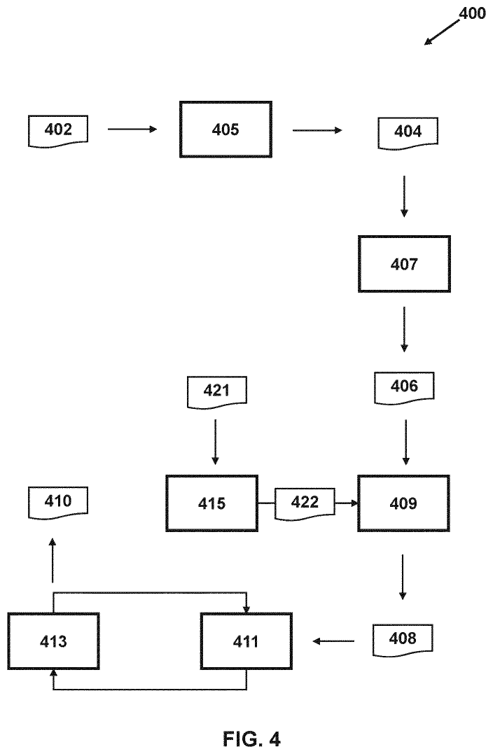

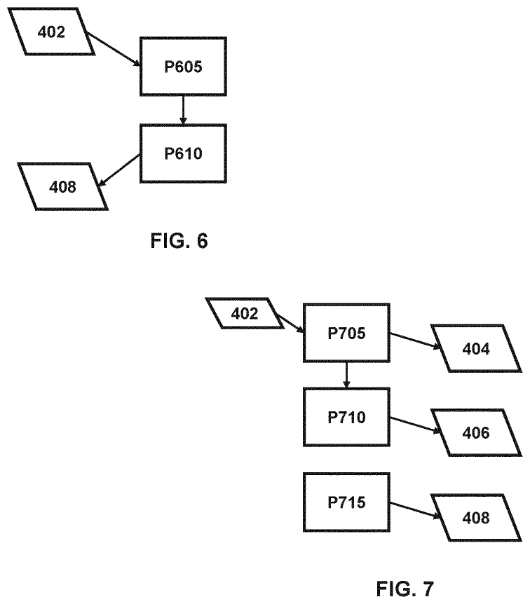

FIG. 4 is a block diagram of an exemplary system 400 for simulating imaging impact in a lithography process due to overlay correction, consistent with various embodiments. FIG. 6 is a flow diagram of an exemplary method for simulating imaging impact in a lithography process due to overlay correction, consistent with various embodiments.

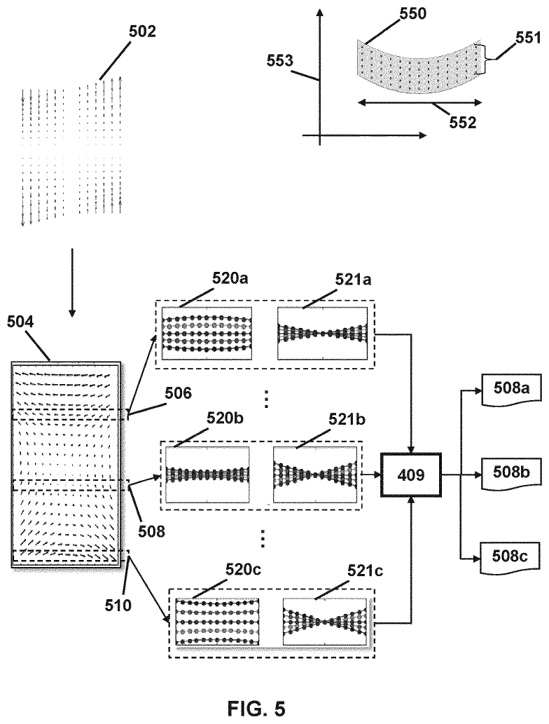

At process P605 of FIG. 6, a fading data component 405 may obtain fading data 402 related to a prescribed overlay correction (e.g., overlay correction terms such as k-terms). The fading data 402 is representative of fading effect induced on wafer printing due to the prescribed overlay correction. In some embodiments, the fading data 402 is representative of position errors of a feature (e.g., in terms of an overlay) over a slit width during slit scanning of the lithographic process (e.g., overlay correction which causes the linear portion of MSD and the image fading). Further, the position errors may be for an entire scanning field and in a scanning direction of the lithographic process. An example scanning slit 550 is illustrated in FIG. 5. FIG. 5 shows examples of fading data, linear portion of the fading data, wavefront expressions used in simulating imaging impact in a lithography process due to prescribed overlay correction, e.g., by stage (e.g., reticle stage MT or wafer stage WT of FIG. 2) modulation according to an embodiment of the present disclosure. A scanning slit 550 has width 552, w, and a height 551, h. The slit can be of various dimensions. For example, the slit width 552 may be “13” units and slit height 551 may be “5” units of scanner measurement grids. A scanning direction of the scanning slit 550 may be the Y direction 553. The scanning field (e.g., scanner exposure area) can be of various dimensions. For example, the scanning field can be of a dimension “19×13” square units where “19” is in the scanning direction, Y 553, and the “13” is in the X direction. The fading data 402 may be represented in various ways. For example, the fading data 402 may be represented as one or more K-terms. An example of the fading data 402, K10 map 502 is shown in FIG. 5. In some embodiments, each arrow in the K10 map 502 is a vector representing the overlay error referenced to a previous layer of a design layout of a target pattern at the same scanning field location. The length of the vector may indicate the magnitude of the overlay correction, and a direction of the arrow may indicate the direction of the overlay correction (e.g., position error). In some embodiments, the overlay correction at each field point of a scanning field may be expressed using a vector (dx,dy), as follows:

$$d x = k 1 + k 3 * x + k 5 * y + k 7 * {x}^{2} + k 9 * xy + k 11 * {y}^{2} + k 13 * {x}^{3} + … \qquad Eq . ( 1 )$$

$$dy = k 2 + k 4 * y + k 6 * x + k 8 * {y}^{2} + k 10 * xy + k 12 * {x}^{2} + k 14 * {y}^{3} + … \qquad Eq . ( 2 )$$

where dx and dy are polynomial expressions of the K-terms, and x and y are co-ordinates of the scanning field.

In some embodiments, the fading data 402 may be derived using overlay measurements (e.g., obtained from a metrology tool). A raw overlay error is generated using the overlay measurements, which is then fit based on Eq. (1) and Eq. (2) for all the k terms which induced the linear portion of MSD.

At process P610, an imaging prediction component 409 simulates a lithography process (e.g., patterning process of FIG. 3) based on the fading data 402 to predict imaging of patterns. In some embodiments, predicting the imaging of patterns may include predicting a set of patterning parameters 408 (e.g., lithography process or lithography apparatus related parameters) such as CD, CDU, ILS, NILS, EPE distribution, PW, LER, PPE, a resist effect, an aberration of a scanner of the lithographic apparatus, or measured mask data. The imaging prediction component 409 may predict the set of parameters 408 using the patterning process, or one or more models, of FIG. 3. In some embodiments, the set of parameters 408 may be predicted for a sub-field or full field of the scanning field. For example, if the scanning field is of a dimension “19×13” field points where “19” field points are in the scanning direction, Y, and “13” field points are in the X direction, the set of parameters 408 may be predicted for (a) the entire area of “19×13” field points, (b) for a sub-field such as a first set of field points 506, which includes all field points at “y=15” (e.g., as shown in FIG. 5), (c) for some of the field points in the first set of field points 506, or (d) for different field points across the scanning field.

In some embodiments, the imaging prediction component 409 may predict the set of patterning parameters 408 based on wavefront expressions. The fading data (e.g., MSD) 402 may be converted to wavefront expressions (e.g., Tatian, Zernike, etc.) such that the imaging impact from the converted wavefront is similar to that from the fading data and the converted wavefront may be used for simulating the imaging impact. In some embodiments, a linear portion of the fading data 402 may be converted to the wavefront expressions (e.g., linear wavefront expressions such as Zernike Z2 and Z3 parameters). Accordingly, the simulation of the imaging impact may include extracting a linear part of the fading data 402 (e.g., linear portion 404 of the MSD, MSDₗᵢₙ), converting the linear portion 404 of the fading data 402 to wavefront expressions 406 (e.g., Z2 and Z3 parameters) and simulating the imaging impact based on the wavefront expressions 406, as described in detail at least with reference to FIG. 7 and FIGS. 4 and 5 above.

FIG. 7 is a flow diagram of a method for simulating imaging impact due to overlay correction using a linear portion of the fading data, consistent with various embodiments. In some embodiments, the method of FIG. 7 may be executed as part of process P610 of FIG. 6.

In some embodiments, MSD may be considered as a combination of linear portion, MSDₗᵢₙ, (e.g., dD/dy) and a non-linear portion (e.g., high order MSD-dⁿ/dyⁿ). In some embodiments, the linear portion, MSDₗᵢₙ may dominate the imaging impact, and therefore, MSDₗᵢₙ, may be considered for predicting the imaging impact. At process P705, the fading data component 405 obtains a linear portion 404 of the fading data 402. In some embodiments, the linear portion 404, MSDₗᵢₙ, is MSD caused by the first order derivative, dD/dy, of the overlay correction term (e.g., k-term of the fading data 402). In some embodiments, MSDₗᵢₙ is the linear part of the MSD of slit intensity weighted standard deviation per field over exposure time/slit length normalized to slit standard deviation. For example, the MSDₗᵢₙ may be expressed as:

$$M S {D}_{l i n} = S t {d}_{slit \_ tilt} * dD / dy \qquad Eq . ( 3 )$$

where Std_{slit_tilt} is the standard deviation, which is weighted by a specific illumination profile across the scan slit height; and dD/dy is the first order derivative of an overlay correction term, D.

Based on the above equation, Eq. (3), the first order derivative of a correction term, D, may be represented as follows:

$$dD / dy = M S {D}_{l i n} / St {d}_{slit \_ tilt} \qquad Eq . ( 4 )$$

The MSDₗᵢₙ 404 may be obtained in a number of ways. For example, the MSDₗᵢₙ 404 may be obtained from a model that determines setpoints for the wafer stage, reticle stage, lens and reticle edge masking assembly (REMA) to perform a correct exposure or alignment scan. In some embodiments, the model will determine the trajectory of the stages and the lens elements during such a scan in the form of a set of polynomials (e.g., from which the MSDₗᵢₙ 404 may be obtained). The model may provide both the MSDₗᵢₙ and high order MSD, and the MSDₗᵢₙ portion may be extracted for use in the prediction. An example of MSDₗᵢₙ 404 is shown as MSDₗᵢₙ K10 map 504 in FIG. 5, which is the linear portion of the overlay correction term-K10 map 502. In some embodiments, a MSDₗᵢₙ 404 value is calculated for each field point in the scanning field. For example, if the scanning field is of the dimension “19×13” field points, then “19×13” MSDₗᵢₙ values are calculated, one for each field point, as illustrated in the MSDₗᵢₙ K10 map 504.

In some embodiments, the Std_{slit_tilt} may be expressed as:

$$S t {d}_{slit \_ tilt} = \sqrt{\{ {\sum }_{i} {w}_{i} {y}_{i}^{2} / {\sum }_{i} {w}_{i} - A ν {g}_{slit \_ tilt}^{2} \}} \qquad Eq . ( 5 )$$

where wᵢ is the weight of an illumination profile of the lithographic apparatus, Yᵢ is i^{th} y location of the slit height 551.

In some embodiments, the Avg_{slit_tilt} may be expressed as:

$${Avg}_{slit \_ tilt} = {\sum }_{i} {w}_{i} {Y}_{i} / {\sum }_{i} {w}_{i} \qquad Eq . ( 6 )$$

where wᵢ is the weight of the illumination profile, Yᵢ is the i^{th} y location of the slit height 551.

At process P710, a wavefront expression component 407 converts the linear portion 404 of the fading data 402 to the wavefront expressions 406 (e.g., Zernike parameters). In some embodiments, the wavefront expression component 407 converts the linear portion 404 of the MSD to linear Zernike parameters (e.g., Z2 or Z3). In some embodiments, Z2 and Z3 are wavefronts covering the whole pupil plane, while Z2 may lead to imaging shift in x dimension and Z3 may lead to imaging shift in y dimension. An example of Z2 or Z3 parameter values are shown in FIG. 5. In some embodiments, the Zernike parameters are obtained for each Yᵢ location of the slit height 551. For example, if the scanning field is of the dimension “19×13” field points, and slit height 551 is “5” units, then “i=1 to 5” and Yᵢ has “5” y values and therefore, “5” Zernike parameter values may be calculated for each field point for a total of “19×13×5” values for each Zernike parameter. In some embodiments, a Zernike parameter may be expressed as a function of an overlay correction term, D, and a numerical aperture (NA) of a source of the lithographic apparatus, as follows:

$${D}_{i} = M S {D}_{l i n} / St {d}_{slit \_ tilt} \qquad Eq . ( 7 )$$

which is representative of a linear part of the displacement at slit location Yᵢ, and

$$Z = D * ( - N A ) \qquad Eq . ( 8 )$$

where Z is the Zernike parameter.

More specifically, Z2 and Z3 parameters may be expressed as follows:

$$Z {2}_{i} = {D}_{i x} * ( - N A ) \qquad Eq . ( 9 )$$

for slit location Yᵢ, where left is negative, and

$$Z {3}_{i} = {D}_{i y} * ( - N A ) \qquad Eq . ( 10 )$$

for slit location Yᵢ, where down is negative.

In the example of FIG. 5, the MSDₗᵢₙ K10 map 504 is converted to Z2 parameter values such as 520a-520c, and Z3 parameter values such as 521a-521c. For example, for a first set of field points 506, which is at “y=15” in the “19×13” scanning field, each of the “13” MSDₗᵢₙ K10 map 504 values in the first set of field points 506 is converted into “5” Z2 values, one for each Yᵢ location of the slit height 551, where “i=5”. Accordingly, for the first set of field points 506, a first set of Z2 values 520a having “13×5=65” values may be generated. The Z2 values may be generated using the equation Eq. (9). Similarly, a first set of Z3 values 521a may be generated for the first set of field points 506 based on the equation Eq. (10). Similarly, the Z2 and Z3 values may be generated for other field point sets. For example, a second set of Z2 values 520b and a second set of Z3 values 521b may be generated for a second set of field points 508, and a third set of Z2 values 520c and third set of Z3 values 521c may be generated for a third set of field points 510. In some embodiments, the wavefront expressions 406 may be generated for portions of the scanning field for which the imaging impact is to be predicted, which can be for a sub-field or full field of the scanning field. In some embodiments, the imaging impact may be predicted for a sub-field, instead of the full-field, to minimize the time or computing resources consumed for the prediction.

At process P715, the imaging prediction component 409 simulates the imaging of patterns to predict a set of patterning parameters 408 based on the wavefront expressions 406. As described above, the set of patterning parameters 408 may include one or more of CD, CDU, ILS, NILS, EPE distribution, PW, LER, PPE, a resist effect, an aberration of a scanner of the lithographic apparatus, or measured mask data. For example, the imaging prediction component 409 may predict a CD for various field points of the scanning area. In another example, the imaging prediction component 409 may predict an EPE distribution for various field points of the scanning area.

In the example of FIG. 5, the imaging prediction component 409 may predict a first set of patterning parameters 508a for the first field points set 506, a second set of patterning parameters 508b for the second field points set 508, and a third set of patterning parameters 508c for the third field points set 510. As described above, the set of patterning parameters 408 may be predicted for a sub-field or full field of the scanning field. For example, the patterning parameters may be predicted for (a) one or more sets of field points such as the first set of field points 506, (b) all sets of field points in the scanning field, or (c) one or more field points in the scanning field.

In some embodiments, the imaging prediction component 409 may input the wavefront expressions 406 (e.g., sets of Z2 values 502a-520c and sets of Z3 values 521a-521c) to a lithographic process or one or more models of the lithographic process of FIG. 3 to predict the set of patterning parameters 408. In some embodiments, the imaging prediction component 409 may use other parameters as well to perform the simulation, e.g., source parameters, mask parameters, etc. In some embodiments, the imaging prediction component 409 may perform the process P715 using the lithographic apparatus and lithographic simulation process described at least with reference to FIGS. 1-3.

While the foregoing paragraphs describe predicting the set of patterning parameters 408 based on a linear portion of the MSD, any portion of the MSD (e.g., non-linear portion of the MSD-MSD high order) may be used for the prediction of the set of patterning parameters 408. Similarly, other Zernike parameters (e.g., non-linear Zernike parameters) or even other wavefront expressions (e.g., Tatian parameters) may be used for the prediction of the set of patterning parameters 408. For example, the fading data 402 may be converted to wavefront expressions other than Zernike for simulating the imaging impact (e.g., Tatian or other wavefront expressions used in simulating the imaging of patterns by a lithography process simulation (e.g., method of FIG. 3)).

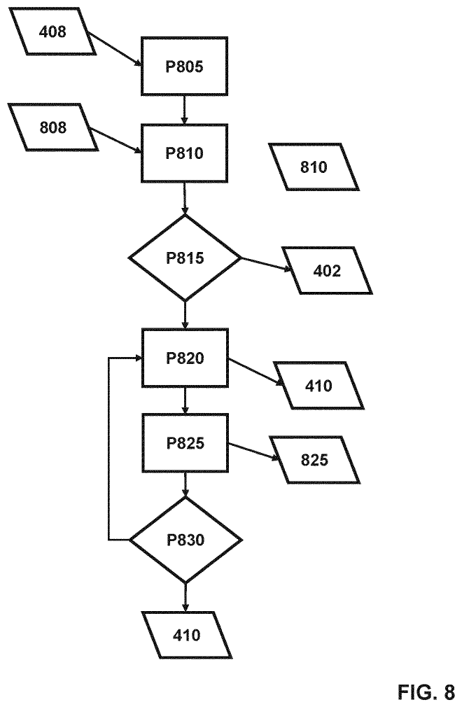

FIG. 8 is a flow diagram of a method for adjusting overlay correction based on imaging impact, consistent with various embodiments. At process P805, an imaging impact component 411 obtains a set of patterning parameters (e.g., set of patterning parameters 408 predicted by the method of FIGS. 6 and 7).

At process P810, the imaging impact component 411 obtains patterning specification data 808 that defines permissible or acceptable parameter values for various patterning parameters. For example, the patterning specification data 808 may define CDₘᵢₙ and CDₘₐₓ values. In another example, the patterning specification data 808 may define process window for the patterning process. In some embodiments, the patterning specification data 808 may be user defined. The imaging impact component 411 compares the values of the set of patterning parameters 408 with the patterning specification data 808 to generate a comparison result 810.

At process P815, the imaging impact component 411 determines whether one or more parameters from the set of patterning parameters satisfies a specified criterion. The specified criterion may depend on the patterning parameter being compared. For example, for a patterning parameter such as CD, the specified criterion may be satisfied if the predicted CD value is within a specified CD range (e.g., CDₘᵢₙ and CDₘₐₓ values) in the patterning specification data 808. In another example, for a patterning parameter such as EPE, the specified criterion may be satisfied if the predicted EPE does not exceed the specified EPE in the patterning specification data 808.

Responsive to a determination that the specified criterion is satisfied, the imaging impact component 411 determines that the prescribed overlay correction does not impact the imaging of patterns on the substrate indicating that a prescribed overlay term (e.g., k-terms) may be used to perform the overlay correction.

Responsive to a determination that the specified criterion is not satisfied, at process P820, the prescribed overlay term is adjusted to minimize the imaging impact. For example, the prescribed overlay correction may be reduced to generate an adjusted overlay correction term 410 (e.g., one or more k-terms may be revised).

At process P825, an overlay simulation component 413 performs a simulation of the overlay correction using the adjusted overlay correction term 410 to generate an overlay simulation result 825. For example, the overlay simulation component 413 may perform micro diffraction-based overlay (uDBO) simulation to predict various overlay parameters, such as corrections per exposure (CPE), overlay across field, etc. as part of the overlay simulation result 825.

At determination process P830, the overlay simulation component 413 determines whether a specified criterion is satisfied. For example, the overlay simulation component 413 may determine whether the overlay parameters in the overlay simulation result 825 satisfies the specified criterion (e.g., are within pre-defined ranges, or match predefined values etc.). In another example, the specified criterion may include the number of iterations performed to adjust the fading data exceeding a specified value. If the specified criterion is not satisfied, the method proceeds to process P820 to continue adjusting the overlay correction term 410. If the specified criterion is satisfied, the overlay simulation component 413 outputs adjusted overlay correction term 410 as the overlay correction terms to be used for performing the overlay corrections.

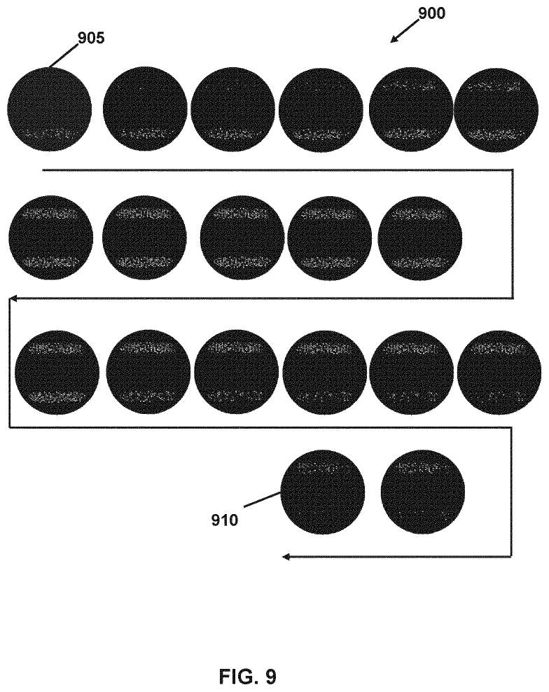

In the foregoing paragraphs, the imaging impact due to overlay correction is simulated based on the fading data (e.g., fading data 402) while having a constant pupil. In some embodiments, a pupil shape changes along the scanning direction, Y 553, and this variation in pupil shape may also have an impact on the imaging of the patterns. FIG. 9 illustrates a dynamic pupil whose shape varies along the scanning direction, consistent with various embodiments. For example, if the scanning field is of a dimension “19×13” square units where “19” is in the scanning direction, Y 553, a pupil shape may vary from a first pupil shape 905 to a nineteenth pupil shape 910 at each field point of the nineteen field points (e.g., a first scanning field point Yᵢ=1 to a nineteenth scanning field point Yᵢ=19. In some embodiments, the dynamic pupil (e.g., a scanning process dependent pupil) may be represented as follows:

$$P ( k ) = A {e}^{Z} , where A is the amplitude , Z is the complex phase . \qquad Eq . ( 11 )$$

In some embodiments, the above pupil shape may include the scanning direction and intra field dependent aberration.

As the pupil shape varies, the transmission cross coefficient (TCC) values may vary, which may impact the generation of an aerial image and thus, the imaging of patterns. In some embodiments, the TCC without the variation in pupil shape may be represented as:

$$T C C ( {k}^{′} , {k}^{″} ) = {\sum }_{k} S ( k ) P ( {k}^{′} + k ) P * ( {k}^{″} + k ) = {\sum }_{j} {λ}_{j} {V}_{j} ( {k}^{′} ) {V}_{j} * ( {k}^{″} ) \qquad Eq . ( 12 )$$

where S(k)=S(kₓ,k_{y}) is source intensity distribution;
M(k)=M(kₓ,k_{y}) is Fourier transform of the mask;
P(k)=P(kₓ,k_{y}) is pupil function;
I(x)=I(x,y) is aerial image intensity.
λⱼ is eigenvalues (real) of TCC decomposition;
Vⱼ(k′) is eigenvectors (complex) of TCC decomposition;
kₓ k_{y} k′ k″ are spatial frequency.

In some embodiments, a pupil shape dependent TCC, that is, the TCC due to the variation in pupil shape may be represented as:

$$T C C = {\sum }_{i} {\sum }_{j} {λ}_{ij} {V}_{ij} ( {k}^{′} ) {V}_{ij} * ( {k}^{″} ) \qquad Eq . ( 13 )$$

where i is scanning location along Yᵢ.

The aerial image due to the variation in pupil shape may be represented as:

$$I ( x ) = {\sum }_{{k}^{′} , {k}^{″}} M ( {k}^{′} ) M * ( {k}^{″} ) TC C ( {k}^{′} , {k}^{″} ) exp ( i ( {k}^{′} - {k}^{″} ) \cdot x ) \qquad Eq . ( 14 )$$

$$I ( x ) = {\sum }_{i} {\sum }_{j} {λ}_{ij} {\vert {V}_{i j} ⊗ M \vert}^{2} \qquad Eq . ( 15 )$$

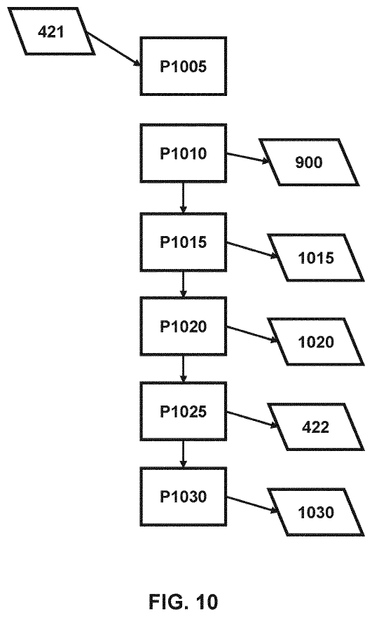

In some embodiments, a pupil management component 415 may determine the various pupil shapes for different scan locations, compute the pupil shape dependent TCC (e.g., using Eq. (13)), and compute an illumination profile weighted TCC 422 based on the pupil shape dependent TCC and slit Y illumination weight profile. The imaging prediction component 409 computes an aerial image or resist contour (e.g., using one or more models of the lithographic process of FIG. 3) based on the illumination profile weighted TCC 422, and further predicts the set of patterning parameters 408 based on the aerial image or resist contour (e.g., and of the wavefront expressions 406). Additional details of computing the aerial image is described at least with reference to FIG. 10 below.

FIG. 10 is a flow diagram of a method for simulating imaging impact due to overlay correction considering an effect of a dynamic pupil, consistent with various embodiments. In some embodiments, the method of FIG. 10 may be executed as part of process P610 of FIG. 6. At process P1005, a target pupil shape 421 is input to the pupil management component 415. In some embodiments, the target pupil shape 421 is determined based on the pupil function:

$$P ( k ) = P ( {k}_{x} , {k}_{y} ) \qquad Eq . ( 16 )$$

where kₓ k_{y} are spatial frequency.

At process P1010, the pupil management component 415 determines a scanning location dependent pupil (e.g., a first pupil shape 905) for each Yᵢ location along the scanning direction, Y 553, to obtain a set of scanning location dependent pupils (e.g., scanning location dependent pupils 900). In some embodiments, the scanning location dependent pupils 900 may include the aberration effect in the scanning direction. In some embodiments, the scanning location dependent pupil may be represented using Eq. (11). The scanning location dependent pupils 900 may be determined in various ways. For example, a scanning location dependent pupil may be determined using measurements obtained from a scanner (e.g., pupils in FIG. 9). In another example, the scanning location dependent pupil may be determined using one or more models (e.g., a machine learning model, an empirical model, a rule-based model, a physical model, a statistical model, an analytics model, or any other empirical model) that are configured to determine the scanning location dependent pupil based on a target pupil. Examples of various pupil shapes 900 are illustrated in FIG. 9.

At process P1015, the pupil management component 415 determines a pupil shape dependent TCC 1015 based on each scanning location dependent pupil shape. For example, the pupil shape dependent TCC 1015 may be determined using Eq. (13).

At process P1020, the pupil management component 415 determines a slit y illumination weight profile 1020 (e.g., scanning slit illumination weight profile) for each scanning location dependent pupil shape. In some embodiments, the slit y illumination weight profile 1020 is determined based on an illumination profile (e.g., scanning slit illumination profile) of each of the scanning location dependent pupil shapes. An example of the slit y illumination profile is illustrated in FIG. 11. In example 1100, a graph is plotted for a slit y illumination profile for each scanning location dependent pupil shape to generate “n” no. (e.g., “19” in “19×13” scanning field) of slit y illumination profiles 1105. In example 1100, the y axis may represent aerial image intensity (or relative weight) and the x-axis may represent the scanning direction location. The slit y illumination profile 1105 of all the scanning location dependent pupil shapes may then be integrated to obtain the slit y illumination weight profile 1020.

At process P1025, the pupil management component 415 determines an illumination profile weighted TCC 422 based on the slit y illumination weight profile 1020 and the pupil shape dependent TCC 1015.

At process P1030, the imaging prediction component 409 computes a pupil shape dependent aerial image 1030 (or resist contour) based on the illumination profile weighted TCC 422. For example, the imaging prediction component 409 may compute the pupil shape dependent aerial image 1030 using Eq. (14) or Eq. (15). In some embodiments, the imaging prediction component 409 may use one or more models of the lithographic process of FIG. 3 to compute the aerial image 1030 (or resist contour). The imaging prediction component 409 may use the computed aerial image 1030 (or resist contour) to predict the set of patterning parameters 408, which may then be used for various purposes (e.g., for adjusting overlay correction based on imaging impact, as described at least with reference to FIG. 8 above).

In some embodiments, the above simulation of imaging impact due to overlay correction helps in improving a patterning process by minimizing defects in patterning a target layout on a substrate. For example, based on the determined imaging impact, a parameter of a patterning process or a lithographic apparatus used to print a pattern on a substrate, or an overlay correction term, may be adjusted to minimize defects in patterning the target layout on the substrate. After adjusting the parameter, the patterning process may be performed using the lithographic apparatus to print patterns corresponding to the target layout on the substrate.

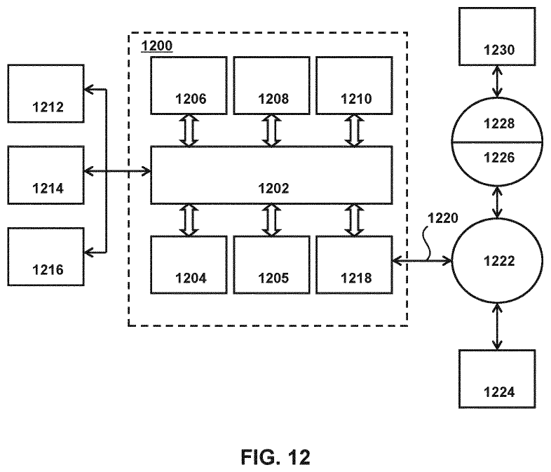

FIG. 12 is a block diagram that illustrates a computer system 1200 which can assist in implementing various methods and systems disclosed herein. The computer system 1200 may be used to implement any of the entities, components, modules, or services depicted in the examples of the figures (and any other entities, components, modules, or services described in this specification). The computer system 1200 may be programmed to execute computer program instructions to perform functions, methods, flows, or services (e.g., of any of the entities, components, or modules) described herein. The computer system 1200 may be programmed to execute computer program instructions by at least one of software, hardware, or firmware.

Computer system 1200 includes a bus 1202 or other communication mechanism for communicating information, and a processor 1204 (or multiple processors 1204 and 1205) coupled with bus 1202 for processing information. Computer system 1200 also includes a main memory 1206, such as a random access memory (RAM) or other dynamic storage device, coupled to bus 1202 for storing information and instructions to be executed by processor 1204. Main memory 1206 also may be used for storing temporary variables or other intermediate information during execution of instructions to be executed by processor 1204. Computer system 1200 further includes a read only memory (ROM) 1208 or other static storage device coupled to bus 1202 for storing static information and instructions for processor 1204. A storage device 1210, such as a magnetic disk or optical disk, is provided and coupled to bus 1202 for storing information and instructions.

Computer system 1200 may be coupled via bus 1202 to a display 1212, such as a cathode ray tube (CRT) or flat panel or touch panel display for displaying information to a computer user. An input device 1214, including alphanumeric and other keys, is coupled to bus 1202 for communicating information and command selections to processor 1204. Another type of user input device is cursor control 1216, such as a mouse, a trackball, or cursor direction keys for communicating direction information and command selections to processor 1204 and for controlling cursor movement on display 1212. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 1200 in response to processor 1204 executing one or more sequences of one or more instructions contained in main memory 1206. Such instructions may be read into main memory 1206 from another computer-readable medium, such as storage device 1210. Execution of the sequences of instructions contained in main memory 1206 causes processor 1204 to perform the process steps described herein. One or more processors in a multi-processing arrangement may also be employed to execute the sequences of instructions contained in main memory 1206. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1204 for execution. Such a medium may take many forms, including but not limited to, non-volatile media, volatile media, and transmission media. Non-volatile media include, for example, optical or magnetic disks, such as storage device 1210. Volatile media include dynamic memory, such as main memory 1206. Transmission media include coaxial cables, copper wire and fiber optics, including the wires that comprise bus 1202. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1204 for execution. For example, the instructions may initially be borne on a magnetic disk of a remote computer. The remote computer can load the instructions into its dynamic memory and send the instructions over a telephone line using a modem. A modem local to computer system 1200 can receive the data on the telephone line and use an infrared transmitter to convert the data to an infrared signal. An infrared detector coupled to bus 1202 can receive the data carried in the infrared signal and place the data on bus 1202. Bus 1202 carries the data to main memory 1206, from which processor 1204 retrieves and executes the instructions. The instructions received by main memory 1206 may optionally be stored on storage device 1210 either before or after execution by processor 1204.

Computer system 1200 also preferably includes a communication interface 1218 coupled to bus 1202. Communication interface 1218 provides a two-way data communication coupling to a network link 1220 that is connected to a local network 1222. For example, communication interface 1218 may be an integrated services digital network (ISDN) card or a modem to provide a data communication connection to a corresponding type of telephone line. As another example, communication interface 1218 may be a local area network (LAN) card to provide a data communication connection to a compatible LAN. Wireless links may also be implemented. In any such implementation, communication interface 1218 sends and receives electrical, electromagnetic, or optical signals that carry digital data streams representing various types of information.

Network link 1220 typically provides data communication through one or more networks to other data devices. For example, network link 1220 may provide a connection through local network 1222 to a host computer 1224 or to data equipment operated by an Internet Service Provider (ISP) 1226. ISP 1226 in turn provides data communication services through the worldwide packet data communication network, now commonly referred to as the “Internet” 1228. Local network 1222 and Internet 1228 both use electrical, electromagnetic, or optical signals that carry digital data streams. The signals through the various networks and the signals on network link 1220 and through communication interface 1218, which carry the digital data to and from computer system 1200, are exemplary forms of carrier waves transporting the information.

Computer system 1200 can send messages and receive data, including program code, through the network(s), network link 1220, and communication interface 1218. In the Internet example, a server 1230 might transmit a requested code for an application program through Internet 1228, ISP 1226, local network 1222 and communication interface 1218. One such downloaded application may provide for the illumination optimization of the embodiment, for example. The received code may be executed by processor 1204 as it is received, or stored in storage device 1210, or other non-volatile storage for later execution. In this manner, computer system 1200 may obtain application code in the form of a carrier wave.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Embodiments of the present disclosure can be further described by the following clauses.
1. A method for determining imaging impact due to overlay correction in a lithography process, the method comprising:
obtaining fading data related to prescribed overlay correction performed by a lithographic apparatus during a lithography process; and
simulating the lithography process based on the fading data to predict imaging of patterns from the lithography process.
2. The method of clause 1, wherein the fading data indicates residual overlay after the prescribed overlay correction.
3. The method of clause 2, wherein the fading data is determined based on simulating modulation of at least one of a wafer stage, a reticle stage, or an optical column of the lithographic apparatus.
4. The method of clause 1, wherein the fading data includes position errors over a slit width during slit scanning of the lithography process.
5. The method of clause 4, wherein the position errors are over a scanning field and in a scanning direction of the lithography process.
6. The method of clause 4, wherein simulating the lithography process includes:
converting the fading data to wavefront expressions as an input to a lithographic model to predict the imaging of patterns.
7. The method of clause 6, wherein converting the fading data to wavefront expressions includes converting the fading data to Zernike wavefront expressions.
8. The method of clause 6, wherein converting the fading data to wavefront expressions includes converting the fading data to Tatian wavefront expressions.
9. The method of clause 6, wherein converting the fading data to the wavefront expressions includes: obtaining a first order derivative of the position errors; and
determining the wavefront expressions based on the first order derivative.
10. The method of clause 9, wherein the first order derivative of the position errors is normalized to a slit standard deviation, wherein the slit standard deviation is weighted by a specific illumination profile across slit height of a scanning slit.
11. The method of clause 6, wherein converting the fading data to the wavefront expressions includes: converting the fading data to linear wavefront expressions.
12. The method of clause 6, wherein the simulating includes predicting the imaging of patterns based on the wavefront expressions.
13. The method of clause 12, wherein the simulating includes predicting the imaging of patterns for a sub-field or full field of scanner exposure area.
14. The method of clause 12, wherein predicting the imaging of patterns includes predicting a set of parameters associated with the lithography process or the patterns.
15. The method of clause 14, wherein the set of parameters includes at least one of a critical dimension (CD) of a pattern, critical dimension uniformity (CDU) of the patterns, image log slope (ILS), normalized image log slope (NILS), edge placement error (EPE) distribution, process window (PW), line edge roughness, or pattern placement error (PPE).
16. The method of clause 12, wherein the simulating includes simulation of a resist effect using a resist model, an aberration of a scanner of the lithographic apparatus, or measured mask data.
17. The method of clause 1 further comprising:
determining whether a set of parameters predicted by the simulating satisfies a specified criterion associated with the lithography process or the patterns.
18. The method of clause 17 further comprising:
responsive to a determination that the specified criterion is not satisfied, adjusting the prescribed overlay correction; and
determining the fading data based on the adjusted prescribed overlay correction.
19. The method of clause 17, wherein the set of parameters satisfies the specified criterion if values of the set of parameters matches values defined in a specification.
20. The method of clause 17 further comprising:
responsive to a determination that the specified criterion is not satisfied, adjusting a parameter of at least one of the lithography process or the lithographic apparatus based on the set of parameters to minimize defects in patterning a target layout on a substrate; and determining the fading data based on adjusted prescribed overlay correction.
21. The method of clause 1, wherein the prescribed overlay correction includes k-terms.
22. The method of clause 1, wherein simulating the lithography process includes:
simulating the lithography process based on an aberration of a target pupil to predict the imaging of patterns from the lithography process.
23. The method of clause 22, wherein simulating the lithography process based on the aberration of the target pupil includes:
generating an aerial image based on an illumination profile weighted transmission cross co efficient (TCC).
24. The method of clause 23, wherein the illumination profile weighted TCC is determined based on a scanning slit illumination weight profile and a pupil shape dependent TCC.
25. The method of clause 24, wherein the scanning slit illumination weight profile is determined based on a set of pupil shapes corresponding to the target pupil, wherein the set of pupil shapes are generated using a function based on an aberration at multiple locations along a scanning direction.
26. The method of clause 25, wherein the scanning slit illumination weight profile is determined based on a scanning slit illumination profile of each pupil shape of the set of pupil shapes.
27. The method of clause 26, wherein the scanning slit illumination profile is determined based on an aerial image intensity of the corresponding pupil shape at a specified location of the locations along the scanning direction.
28. The method of clause 25, wherein the scanning slit illumination weight profile is determined based on an integration of aerial image intensity of the set of pupil shapes.
29. The method of clause 24, wherein the pupil shape dependent TCC is determined based on a set of pupil shapes corresponding to a target pupil, wherein the set of pupil shapes are generated using a function based on aberration at multiple locations along a scanning direction.
30. The method of clause 29, wherein the set of pupil shapes includes a first pupil shape at a first location of the multiple locations along the scanning direction.
31. The method of clause 30, wherein each pupil shape of the set of pupil shapes is determined using a function based on an amplitude and a complex phase associated with an illumination source of the lithographic apparatus.
32. The method of clause 30, wherein each pupil shape of the set of pupil shapes is determined based on measurements obtained from the lithographic apparatus.
33. The method of clause 30, wherein each pupil shape of the set of pupil shapes is predicted based on the target pupil and one or more parameters associated with the lithographic apparatus or the lithography process.
34. A method for determining imaging impact due to overlay correction in a lithography process, the method comprising:
obtaining fading data related to prescribed overlay correction performed by a lithographic apparatus during a lithography process;
converting the fading data to wavefront expressions as an input to predict imaging of patterns; and
simulating the lithography process based on the wavefront expressions to predict the imaging of patterns.
35. The method of clause 34, wherein the fading data indicates residual overlay after the prescribed overlay correction.
36. The method of clause 35, wherein the fading data is determined based on simulating modulation of at least one of a wafer stage, a reticle stage, or an optical column of the lithographic apparatus.
37. The method of clause 35, wherein the fading data includes position errors over a slit width during slit scanning of the lithography process.
38. The method of clause 37, wherein converting the fading data to the wavefront expressions includes: obtaining a first order derivative of the position errors; and determining the wavefront expressions based on the first order derivative.
39. The method of clause 38, wherein the first order derivative of the position errors is normalized to slit standard deviation, wherein the slit standard deviation is weighted by a specific illumination profile across slit height of a scanning slit.
40. The method of clause 35, wherein converting the fading data to the wavefront expressions includes: converting the fading data to linear wavefront expressions.
41. The method of clause 35, wherein the simulating includes predicting the imaging of patterns based on the wavefront expressions.
42. The method of clause 41, wherein the imaging of patterns is predicted for a sub-field or full field of scanner exposure area.
43. The method of clause 41, wherein the predicting the imaging of patterns includes predicting a set of parameters associated with the lithography process or the patterns.
44. The method of clause 43, wherein the set of parameters includes at least one of a critical dimension (CD) of a pattern, critical dimension uniformity (CDU) of the patterns, image log slope (ILS), normalized image log slope (NILS), edge placement error (EPE) distribution, process window (PW), line edge roughness, or pattern placement error (PPE).
45. The method of clause 35, wherein the simulating includes simulation of a resist effect using a resist model, an aberration of a scanner of the lithographic apparatus, or measured mask data.
46. The method of clause 34 further comprising:
determining whether a set of parameters predicted by the simulating satisfies a specified criterion associated with the lithography process or the patterns.
47. The method of clause 46 further comprising:
responsive to a determination that the specified criterion is not satisfied, adjusting the prescribed overlay correction; and
determining the fading data based on the adjusted prescribed overlay correction.
48. The method of clause 46, wherein the set of parameters satisfies the specified criterion if values of the set of parameters matches values defined in a specification.
49. A method for simulating a lithography process based on a dynamic pupil, the method comprising:
obtaining a set of pupil shapes corresponding to a target pupil, the set of pupil shapes corresponding to a variation of the target pupil at multiple locations along a scanning direction of a lithographic apparatus; and
simulating a lithography process based on the set of pupil shapes to predict imaging of patterns from the lithography process.
50. The method of clause 49, wherein obtaining the set of pupil shapes includes:
obtaining the set of pupil shapes based on an aberration of the target pupil.
51. The method of clause 50, wherein the set of pupil shapes are generated using a function based on the aberration of the target pupil at the multiple locations along the scanning direction.
52. The method of clause 49, wherein simulating the lithography process based on the set of pupil shapes includes:
generating an aerial image based on an illumination profile weighted transmission cross co efficient (TCC).
53. The method of clause 52, wherein simulating the lithography process includes:
predicting the imaging of patterns based on the aerial image, wherein predicting the imaging of patterns includes predicting a set of parameters associated with the lithography process or the patterns.
54. The method of clause 52, wherein the illumination profile weighted TCC is determined based on a scanning slit illumination weight profile and a pupil shape dependent TCC.
55. The method of clause 54, wherein the scanning slit illumination weight profile is determined based on the set of pupil shapes.
56. The method of clause 54, wherein the scanning slit illumination weight profile is determined based on a scanning slit illumination profile of each pupil shape of the set of pupil shapes.
57. The method of clause 56, wherein the scanning slit illumination profile is determined based on an aerial image intensity of the corresponding pupil shape at a specified location of the locations along the scanning direction.
58. The method of clause 55, wherein the scanning slit illumination weight profile is determined based on an integration of aerial image intensity of the set of pupil shapes.
59. The method of clause 54, wherein the pupil shape dependent TCC is determined based on the set of pupil shapes.
60. The method of clause 49, wherein the set of pupil shapes includes a first pupil shape at a first location of the multiple locations along the scanning direction.
61. The method of clause 49, wherein each pupil shape of the set of pupil shapes is determined using a function based on an amplitude and a complex phase associated with an illumination source of the lithographic apparatus.
62. The method of clause 49, wherein each pupil shape of the set of pupil shapes is determined based on measurements obtained from the lithographic apparatus.
63. The method of clause 49, wherein each pupil shape of the set of pupil shapes is predicted based on the target pupil and one or more parameters associated with the lithographic apparatus or the lithography process.
64. An apparatus, the apparatus comprising:
a memory storing a set of instructions; and
a processor configured to execute the set of instructions to cause the apparatus to perform a method of any of the above clauses.
65. A non-transitory computer-readable medium having instructions recorded thereon, the instructions when executed by a computer implementing the method of any of the above clauses.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

The descriptions herein are intended to be illustrative, not limiting. Thus, it will be apparent to one skilled in the art that modifications may be made as described without departing from the scope of the claims set out below.

1. A method for determining imaging impact due to overlay correction in a lithography process, the method comprising:
obtaining fading data related to prescribed overlay correction performed by a lithographic apparatus during a lithography process; and
simulating, by a hardware computer, the lithography process based on the fading data to predict imaging of a pattern from the lithography process.

2. The method of claim 1, wherein the fading data indicates residual overlay after the prescribed overlay correction.

3. The method of claim 2, wherein the fading data is determined based on simulating modulation of at least one selected from: of a wafer stage, a reticle stage, or an optical column of the lithographic apparatus.

4. The method of claim 1, wherein the fading data includes position errors over a slit width during slit scanning of the lithography process.

5. The method of claim 4, wherein the position errors are over a scanning field and in a scanning direction of the lithography process.

6. The method of claim 1, wherein simulating the lithography process includes converting the fading data to one or more wavefront expressions as an input to a lithographic model to predict the imaging of patterns, wherein converting the fading data to one or more wavefront expressions includes converting the fading data to one or more Zernike or Tatian wavefront expressions.

7. The method of claim 6, wherein converting the fading data to the one or more wavefront expressions includes:
obtaining a first order derivative of the position errors; and
determining the one or more wavefront expressions based on the first order derivative.

8. The method of claim 7, wherein the first order derivative of the position errors is normalized to a slit standard deviation, wherein the slit standard deviation is weighted by a specific illumination profile across slit height of a scanning slit.

9. The method of claim 6, wherein converting the fading data to the one or more wavefront expressions includes converting the fading data to one or more linear wavefront expressions.

10. The method of claim 6, wherein the simulating includes predicting the imaging of a pattern based on the one or more wavefront expressions.

11. The method of claim 10, wherein the simulating includes predicting the imaging of a pattern for a sub-field or full field of scanner exposure area.

12. The method of claim 10, wherein predicting the imaging of the pattern includes predicting a set of parameters associated with the lithography process or the pattern, and wherein the set of parameters includes at least one selected from: a critical dimension (CD) of a pattern, critical dimension uniformity (CDU) of patterns, image log slope (ILS), normalized image log slope (NILS), edge placement error (EPE) distribution, process window (PW), line edge roughness, or pattern placement error (PPE).

13. The method of claim 1, wherein the simulating includes simulation of a resist effect using a resist model, an aberration of a scanner of the lithographic apparatus, or measured mask data.

14. The method of claim 1, further comprising:
determining whether a set of parameters predicted by the simulating satisfies a specified criterion associated with the lithography process or the pattern;
responsive to a determination that the specified criterion is not satisfied, adjusting the prescribed overlay correction; and
determining the fading data based on the adjusted prescribed overlay correction.

15. The method of claim 1, wherein the prescribed overlay correction includes k-terms.

16. A non-transitory computer-readable medium comprising stored instructions, the instructions, when executed by a computer system, configured to cause the computer system to at least:
obtain fading data related to prescribed overlay correction performed by a lithographic apparatus during a lithography process; and
simulate the lithography process based on the fading data to predict imaging of a pattern from the lithography process.

17. The medium of claim 16, wherein the fading data indicates residual overlay after the prescribed overlay correction.

18. The medium of claim 17, wherein the fading data is determined based on simulation of modulation of at least one selected from: a wafer stage, a reticle stage, or an optical column of the lithographic apparatus.

19. The medium of claim 16, wherein the fading data includes position errors over a slit width during slit scanning of the lithography process.

20. The medium of claim 16, wherein instructions configured to cause the computer system to simulate the lithography process are further configured to cause the computer system to convert the fading data to one or more wavefront expressions as an input to a lithographic model to predict the imaging of patterns, wherein conversion of the fading data to one or more wavefront expressions includes conversion of the fading data to one or more Zernike or Tatian wavefront expressions.
